(19) United States
(12) Patent Application Publication
(10) Pub. No.: US 2002/0097095 A1
(43) Pub. Date: Jul. 25, 2002

(54) Temperature compensation circuit for a power amplifier

(75) Inventors: Hu-Myung Jeon, Kyonggi-do (KR); Jae-Wook Rheem, Kyonggi-do (KR)

Correspondence Address: Paul J. Farrell, Esq., DILWORTH & BARRESE, LLP, 333 Earle Ovington Blvd., Uniondale, NY, 11553, US

(73) Assignee: SAMSUNG ELECTRONICS CO., LTD., KYUNGKI-DO (KR)

(21) Appl. No.: 09/855,296

(22) Filed: May 15, 2001

(30) Foreign Application Priority Data
Jan. 19, 2001 (KR) 3103/2001

(51) Int. Cl. H03F 3/04

(52) U.S. Cl. 330/289

(57) ABSTRACT

Disclosed is a temperature compensation circuit for a power amplifier that is capable of stabilizing a variation in current of a bias circuit. The temperature compensation circuit comprises a bias voltage node for providing a bias voltage to the power amplifier; a regulated voltage node connected to a regulated voltage; a temperature sensor connected between the bias voltage node and a ground node, the temperature sensor having a resistance varying according to ambient temperature; a first resistor connected in parallel to the temperature sensor, for reducing a variation in resistance of the temperature sensor; and a second resistor connected between the regulated voltage node and the bias voltage node, for dividing the regulated voltage to generate the bias voltage.

### PRIORITY

This application claims priority to an application entitled “Temperature Compensation Circuit for Power Amplifier” filed in the Korean Industrial Property Office on Jan. 19, 2001 and assigned Ser. No. 2001-3103, the contents of which are hereby incorporated by reference.

### BACKGROUND OF THE INVENTION

1. Field of the Invention

The present invention relates generally to a power amplifier in a communication terminal, and in particular, to a temperature compensation circuit for stabilizing a variation in current of a bias circuit according to the ambient temperature.

2. Description of the Related Art

In a power amplifier, a bias current (or an operating point current) is an important factor, which determines a characteristic of the power amplifier. In general, a variation in current of a bias circuit according to the ambient temperature affects the fundamental characteristics of the power amplifier, such as a gain and an adjacent channel protection ratio (ACPR). The current variation becomes more significant at low temperatures. Here, the ACPR indicates to a degree, how an original signal generated at a transmission stage of a communication terminal interferes with an adjacent channel through spurious or noise floor.

FIG. 1 illustrates an equivalent circuit of a power amplifier. A bias voltage of the power amplifier is either fixed or varied by a control circuit (not shown) according to the type and structure of the power amplifier. Here, the control circuit can be connected to the bias voltage node Vref. Even though a voltage regulator (not shown) provides a constant voltage to a bias voltage node Vref of the power amplifier via its output node Vt, the bias current varies according to the ambient temperature.

The conventional power amplifier with a non-temperature compensated control circuit has the following disadvantages.

First, the gain or the ACPR characteristic of the power amplifier varies according to the ambient temperature. This is because the bias current (or operating point current) varies according to the ambient temperature, even though a constant bias voltage is provided to the bias circuit of the power amplifier through the bias voltage node Vref.

Second, the bias current increases at high temperatures. Therefore, at high temperatures, the maximum power of the power amplifier decreases, whereas the minimum power increases (see FIGS. 4A and 4B). In contrast, the bias current decreases at low temperatures. Hence, at low temperatures, the maximum power of the power amplifier increases, whereas the minimum power decreases. The variation of the bias current becomes considerable when the power amplifier has a low gain or receives a low-power input signal.

Third, when the power amplifier has a low gain or receives a low-power input signal at low temperatures, the minimum power will be considerably decreased. In particular, if the minimum power is considerably decreased, a step gain power amplifier may be shut down.

Fourth, the existing power amplifier performs temperature compensation by software. Therefore, when the variation in output power (or gain) according to the ambient temperature is considerable, the power amplifier has limitations on accurate temperature compensation.

FIG. 2 illustrates a prior art fixed-gain power amplifier such as the RI123124U and RM912 by Conexant, USA. The fixed-gain power amplifier is provided with a bias voltage Vref, which is either fixed or variable between 2.6 V and 3.2 V.

FIG. 3 illustrates a prior art step gain power amplifier. The step gain amplifier is provided with a fixed bias voltage Vref, and varies an output gain step by step according to mode control signals applied to its mode control nodes Vmode1 and Vmode2. Having two mode control nodes Vmode1 and Vmode2, the step gain amplifier of FIG. 3 can operate in three operation modes: a high-power mode, an intermediate-power mode and a low-power mode.

FIGS. 4A and 4B illustrate temperature-to-output power characteristics of a general power amplifier. Specifically, FIG. 4A illustrates a temperature-to-output power characteristic for the relatively high output power (or the maximum power) of the power amplifier, and FIG. 4B illustrates a temperature-to-output power characteristic for the relatively low output power (or the minimum power). Referring to FIG. 4A, the maximum power decreases at high temperature, and increases at low temperature. It is noted that a difference between a reference output power 25 dBm and the maximum power at the temperatures of −30° C. and 60° C. is about 2-3 dBm. Specifically, while the maximum power is equal to the reference power of 25 dBm at 25° C., the maximum power is higher by about 2 dBm than the reference power of 25 dBm at −30° C. and is lower by about 3 dBm than the reference power of 25 dBm at 60° C.

On the contrary, as illustrated in FIG. 4B, the minimum power increases at high temperature and decreases at the temperature. The minimum power is lower by about 9 dBm than the reference power of −55 dBm at −30° C. and is higher by about 10 dBm than the reference power at 60° C.

A bias voltage is provided to the bias voltage node Vref for a driver stage in the power amplifier. The bias current varies according to the ambient temperature. To be more specific, the bias current increases at high temperature and decreases at low temperature.

FIG. 5 illustrates a current characteristic of the step gain amplifier. An idle current becomes 35, 70 and 100 mA at the respective steps, and this current varies about 20-30 mA at high temperature and low temperature on the basis of room temperature. That is, the maximum power varies about 2-3 dBm and the minimum power varies about 9-10 dBm. The variation of the minimum power according to temperature is significant, and in the worst case, the power amplifier may be shut down. In the step gain amplifier, this phenomenon occurs more frequently at the low-gain mode. Actually, a smart power amplifier is shut down, if the temperature decreases in the low-power mode.

### SUMMARY OF THE INVENTION

It is, therefore, an object of the present invention to provide a temperature compensation circuit for a power amplifier, capable of stabilizing a variation in current of a bias circuit.

In accordance with one aspect of the present invention, a temperature compensation circuit for a power amplifier, comprises a bias voltage node for providing a bias voltage to the power amplifier; a regulated voltage node connected to a regulated voltage; a temperature sensor connected between the bias voltage node and a ground node, the temperature sensor, preferably an NTC (Negative Temperature Coefficient) thermistor, having a resistance varying according to ambient temperature; a first resistor connected in parallel to the temperature sensor, for reducing a variation in resistance of the temperature sensor; and a second resistor connected between the regulated voltage node and the bias voltage node, for dividing the regulated voltage to generate the bias voltage. Further, the temperature compensation circuit comprises a bypass capacitor connected between the bias voltage node and the ground node.

In accordance with another aspect of the present invention, a temperature compensation circuit for a power amplifier, comprises a bias voltage node for providing a bias voltage to the power amplifier; a regulated voltage node connected to a regulated voltage; a temperature sensor, preferably a PTC (Positive Temperature Coefficient) thermistor, connected between the bias voltage node and the regulated voltage node, the temperature sensor having a resistance varying according to ambient temperature; a first resistor connected in parallel to the temperature sensor, for reducing a variation in resistance of the temperature sensor; and a second resistor connected between the bias voltage node and a ground node, for dividing the regulated voltage to generate the bias voltage.

### BRIEF DESCRIPTION OF THE DRAWINGS

The above and other objects, features and advantages of the present invention will become more apparent from the following detailed description when taken in conjunction with the accompanying drawings in which:

FIG. 1 is a diagram illustrating an equivalent circuit of a power amplifier;

FIG. 2 is a diagram illustrating a fixed-gain power amplifier;

FIG. 3 is a diagram illustrating a step gain power amplifier;

FIGS. 4A and 4B are graphs illustrating temperature-to-output power characteristics of a general power amplifier;

FIG. 5 is a graph illustrating a current characteristic of a step gain power amplifier;

FIG. 6 is a diagram illustrating an equivalent circuit of a temperature-compensated power amplifier according to an embodiment of the present invention;

FIG. 7 is a diagram illustrating an equivalent circuit of a temperature-compensated power amplifier according to another embodiment of the present invention; and

FIG. 8 is a graph illustrating a current characteristic of a power amplifier supporting a high-power mode and an intermediate-power mode.

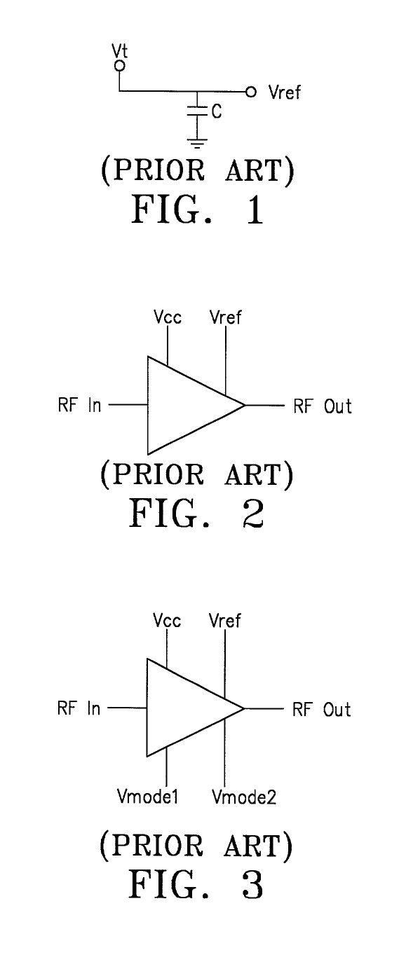

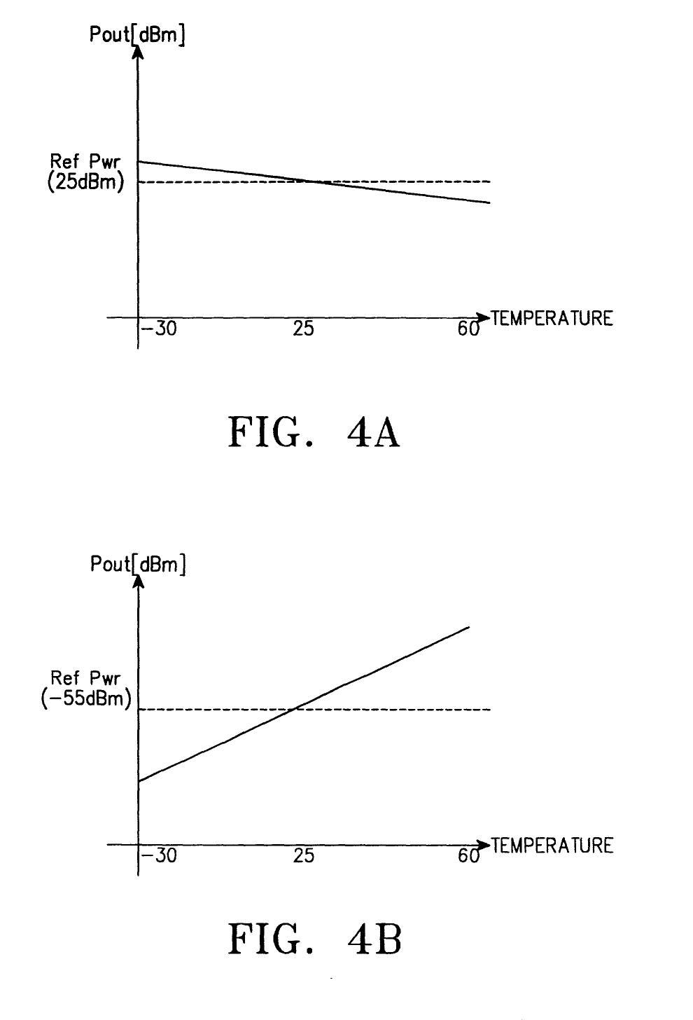

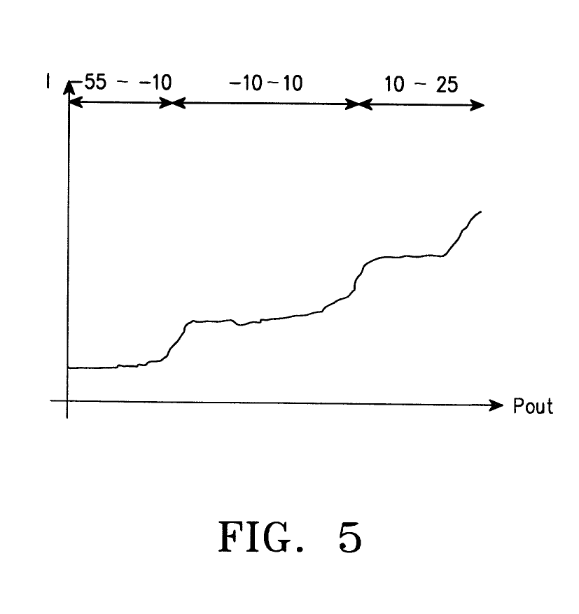

### DETAILED DESCRIPTION OF THE PREFERRED EMBODIMENT

A preferred embodiment of the present invention will be described herein below with reference to the accompanying drawings. In the following description, well-known functions or constructions are not described in detail since they would obscure the invention in unnecessary detail.

A thermistor, as a temperature sensor, is classified into an NTC Negative Temperature Coefficient) type having a low resistance at high temperatures and a PTC (Positive Temperature Coefficient) type having a high resistance at high temperatures.

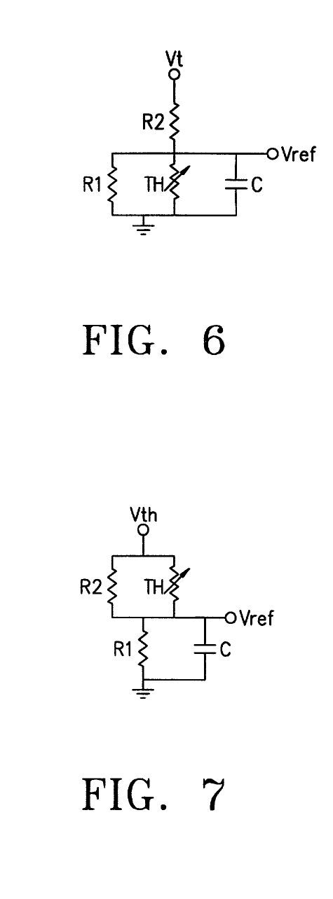

FIG. 6 illustrates an equivalent circuit of a temperature-compensated power amplifier according to an embodiment of the present invention, and FIG. 7 illustrates an equivalent circuit of a temperature-compensated power amplifier according to another embodiment of the present invention.

Referring to FIG. 6, Vref denotes a bias voltage node used to provide a bias voltage to a bias circuit of the power amplifier. The bias voltage is about 2.6-3.2 V according to the type of the power amplifier. Further, Vt denotes an output node of a voltage regulator, TH denotes a temperature sensor comprised of a thermistor, and C denotes a bypass capacitor. In addition, R2 denotes a voltage-dividing resistor and R1 denotes a resistor used to reduce a variation in resistance of the thermistor TH according to the ambient temperature (where R1>>R2).

The thermistor TH has a higher resistance at lower temperatures and a lower resistance at higher temperatures. In other words, the thermistor TH of FIG. 6 is preferably an NTC thermistor. The circuit shown in FIG. 6 is constructed using such a characteristic of the thermistor. In FIG. 6, a regulated voltage provided to the node Vt is divided by the resistors R2 and R1 and the thermistor TH in accordance with the following formula, and the divided voltage is provided to the bias voltage node Vref.

Vref=Vt*((R1/TH)/(R2+(R1/TH)))

As a result, the bias voltage is decreased at the high temperature, decreasing the bias current of the power amplifier. In contrast, the bias voltage is increased at the low temperature, increasing the bias current. Therefore, the power amplifier can maintain its constant characteristic regardless of the temperature variation. That is, the power amplifier has a temperature-compensated characteristic.

The circuit shown in FIG. 7 also operates in the same manner. However, the circuit includes a PTC thermistor, which has a lower resistance at lower temperatures and a higher resistance at higher temperatures. A first resistor R1 is connected in parallel to a thermistor TH, connected between a supply voltage node Vt and a bias voltage node Vref, in order to reduce a variation in resistance of the thermistor TH according to the ambient temperature. A second resistor R2 is connected between the bias voltage node Vref and a ground node to divide the regulated supply voltage Vt. The divided voltage is determined by the following formula and provided to the bias voltage node Vref.

Vref=Vt*(R2/(R2+(R1/TH)))

When actually realized, the circuits of FIGS. 6 and 7 may have somewhat different outcomes from their associated formulas because of an impedance of the bias voltage node Vref, a PCB (Printed Circuit Board) pattern loss, and errors of the resistors and the thermistor. All in all, however, the circuits will have virtually the same characteristics as their associated formulas. In use, the circuits of FIGS. 6 and 7 may be incorporated in a mobile phone. Although the circuits may additionally include a circuit for controlling the bias voltage and a circuit for improving the call efficiency of the mobile phone, the fundamental structure of the temperature compensation circuit with the thermistor remains the same.

The invention can also be applied to a smart power amplifier to decrease an output current over an overall power range. This will be described with reference to FIG. 3.

The smart power amplifier shown in FIG. 3 operates in three operation modes, including high-power mode, intermediate-power mode and low-power mode. In the high-power mode, the smart power amplifier has a high gain and high current consumption. In the intermediate-power mode, the smart power amplifier has an intermediate gain and intermediate current consumption. Further, in the low-power mode, the smart power amplifier has a low gain and low current consumption. Therefore, it is possible to decrease current consumption of the communication terminal by allowing the power amplifier to operate in the low-power mode at an output power range between −55 dBm to −10 dBm. However, in the low-power mode, the power amplifier has an increased variation in the minimum power and, in the worst case, may be shut down at the low temperature (about −30° C.). Therefore, the power amplifier cannot normally operate in the low-power mode at the low temperature, without using a temperature compensation circuit with the thermistor. In this case, the power amplifier must operate in the high-power mode or the intermediate-power mode, or change (preferably increase) the number of operation modes according to temperature.

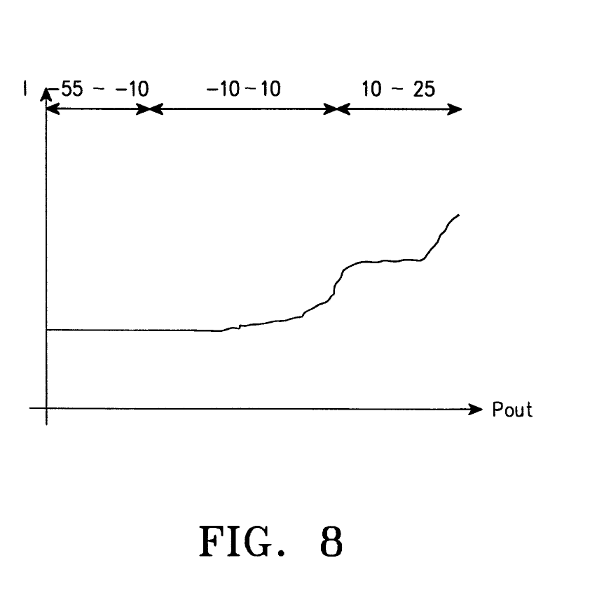

FIG. 8 illustrates a current characteristic of the step gain power amplifier supporting the high-power mode and the intermediate-power mode. When supporting the two power modes, the step gain power amplifier operates in the intermediate-power mode instead of the low-power mode in the output power range between −55 dBm to −10 dBm. Therefore, the communication terminal consumes the increased current. However, when using the temperature compensation circuit with the thermistor according to an embodiment of the present invention, the step gain power amplifier can operate even in the low-power mode, since a variation in gain of each power mode according to the temperature is less. By applying this to the communication terminal, it is possible to drive the communication terminal with a decreased current at the output power range between −55 dBm to −10 dBm (this range can be varied according to the communication terminals).

As described above, the present invention minimizes a variation in characteristic of the power amplifier according to ambient temperature by using a temperature compensation circuit. In addition, it is possible to decrease a call current by utilizing the characteristic of the power amplifier in the low-power mode. Therefore, it is also possible to maintain the same characteristic of the communication terminal even in a severe environment. In addition, the output power of the communication terminal increases at the low temperature, preventing attenuation of the output power, thereby making it possible to maintain the probability of transmission success. In addition, the temperature compensation circuit can be applied not only to the power amplifier for use in existing communication terminals but also to the power amplifier for use in future CDMA-2000 or IMT-2000 communication terminals.

While the invention has been shown and described with reference to a certain preferred embodiment thereof, it will be understood by those skilled in the art that various changes in form and details may be made therein without departing from the spirit and scope of the invention as defined by the appended claims.

What is claimed is:

1. A temperature compensation circuit for a power amplifier, the circuit comprising:
a bias voltage node for providing a bias voltage to the power amplifier;
a regulated voltage node connected to a regulated voltage;
a temperature sensor connected between the bias voltage node and a ground node, the temperature sensor having a resistance varying according to ambient temperature;
a first resistor connected in parallel to the temperature sensor, for reducing a variation in resistance of the temperature sensor; and
a second resistor connected between the regulated voltage node and the bias voltage node, for dividing the regulated voltage to generate the bias voltage.

2. The temperature compensation circuit as claimed in claim 1, further comprising a bypass capacitor connected between the bias voltage node and the ground node.

3. The temperature compensation circuit as claimed in claim 1, wherein the temperature sensor is an NTC (Negative Temperature Coefficient) thermistor.

4. The temperature compensation circuit as claimed in claim 3, wherein the bias voltage is determined by a following formula:
Vref=Vt*((R1/TH)/(R2+(R1/TH)))
where Vref denotes the bias voltage, Vt denotes the regulated voltage, R1 denotes a resistance of the first resistor, R2 denotes a resistance of the second resistor, and TH denotes a resistance of the thermistor.

5. A temperature compensation circuit for a power amplifier, the circuit comprising:
a bias voltage node for providing a bias voltage to the power amplifier;
a regulated voltage node connected to a regulated voltage;
a temperature sensor connected between the bias voltage node and the regulated voltage node, the temperature sensor having a resistance varying according to ambient temperature;
a first resistor connected in parallel to the temperature sensor, for reducing a variation in resistance of the temperature sensor; and
a second resistor connected between the bias voltage node and a ground node, for dividing the regulated voltage to generate the bias voltage.

6. The temperature compensation circuit as claimed in claim 5, further comprising a bypass capacitor connected between the bias voltage node and the ground node.

7. The temperature compensation circuit as claimed in claim 5, wherein the temperature sensor is a PTC (Positive Temperature Coefficient) thermistor.

8. The temperature compensation circuit as claimed in claim 7, wherein the bias voltage is determined by a following formula:
Vref=Vt*(R2/(R2+(R1/TH)))
where Vref denotes the bias voltage, Vt denotes the regulated voltage, R1 denotes a resistance of the first resistor, R2 denotes a resistance of the second resistor, and TH denotes a resistance of the thermistor.
